(19) United States
(12) Patent Application Publication
(10) Pub. No.: US 2021/0348857 A1
(43) Pub. Date: Nov. 11, 2021

(54) HEAT DISSIPATION STRUCTURE

(71) Applicant: Tung-Mao WANG, New Taipei City (TW)

(72) Inventor: Tung-Mao WANG, New Taipei City (TW)

(21) Appl. No.: 17/198,502

(22) Filed: Mar. 11, 2021

(30) Foreign Application Priority Data
May 5, 2020 (TW) 109205377

(51) Int. Cl. F28F 13/12; H05K 7/20

(52) U.S. Cl. CPC F28F 13/12; F28F 2215/08; H05K 7/2039

(57) ABSTRACT

A heat dissipation structure includes primarily plural cooling fins. A flow space for air flow is defined between every two cooling fins, and at least a through-hole which is connected with the flow space is defined on each cooling fin. Therefore, the air speed can be increased, so that heat will not be accumulated easily and can be removed out rapidly, thereby improving the heat removal efficiency of the heat dissipation structure. In addition, as each cooling fin is provided with plural through-holes, the weight of entire finished product can be decreased indirectly.

### BACKGROUND OF THE INVENTION

### a) Field of the Invention

The present invention relates to a heat dissipation structure, and more particularly to an improved heat dissipation structure.

### b) Description of the Prior Art

As the progress of technology, all of the equipment that generates high temperature by operation, such as a processor, a display card GPU (Graphics Processing Unit), or a transformer, will be cooled down by a finned heat sink which is provided with a higher heat dissipation efficiency. This kind of heat sink is primarily composed of plural cooling fins, and a heat dissipation space with fixed distance is kept between the cooling fins, so that temperature can be reduced rapidly by air convection. Although this kind of heat sink is provided with a high efficient heat dissipation effect, if the cooling fins are many, the entire weight is heavy; and as air only flows toward one direction, the heat dissipation effect cannot be improved further.

### SUMMARY OF THE INVENTION

A primary object of the present invention is to provide a heat dissipation structure, wherein air speed is increased by through-holes that are defined on each cooling fin as well as by convection between the through-holes and a flow space. Therefore, heat will not be accumulated easily and can be removed out rapidly, thereby improving the heat dissipation efficiency of the heat dissipation structure. In addition, as each cooling fin is provided with plural through-holes, the weight of entire finished product is decreased indirectly.

To achieve the abovementioned object, the present invention provides a heat dissipation structure, comprising plural cooling fins. A flow space for air flow is defined between every two cooling fins, and each cooling fin is defined at least a through-hole which is connected with the flow space.

According to an embodiment of the present invention, there can be plural through-holes on the cooling fin.

According to an embodiment of the present invention, each through-hole on one cooling fin is partly overlapped with each through-hole on a neighboring cooling fin.

According to an embodiment of the present invention, each through-hole on one cooling fin is completely overlapped with each through-hole on a neighboring cooling fin.

According to an embodiment of the present invention, each through-hole on one cooling fin is not overlapped with each through-hole on a neighboring cooling fin.

According to an embodiment of the present invention, the air flow direction of the through-hole on the cooling fin is perpendicular to the direction of air flow in the flow space.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a three-dimensional schematic view of a preferred embodiment of the present invention.

FIG. 2 shows a three-dimensional exploded view of the preferred embodiment of the present invention.

FIG. 3 shows a schematic view of air flow direction along a section line AA in FIG. 1.

FIG. 4 shows a state diagram of the present invention that the through-holes on the cooling fin are partly overlapped with the through-holes on a neighboring cooling fin.

FIG. 5 shows a state diagram of the present invention that the through-holes on the cooling fin are completely overlapped with the through-holes on the neighboring cooling fin.

FIG. 6 shows a state diagram of the present invention that the through-holes on the cooling fin are not overlapped with the through-holes on the neighboring cooling fin.

### DETAILED DESCRIPTION OF THE PREFERRED EMBODIMENTS

The structure, ratio, size, etc. shown in the accompanying drawings in this specification are only used associatively with the content disclosed in this specification, for the comprehension by those who are familiar with this technique. They are not to be used to limit the implementation of the present invention, and thus, do not have any physical meaning in terms of the technique. Any modification in structure, change in ratio or adjustment in size, should be still within the range covered in the technical content disclosed by the present invention, without affecting the efficacy and object achieved by the present invention. Meanwhile, the word employed in this specification, such as “one,” “two,” or “upper” is only for the convenience in description, and is not used to limit the range of implementation of the present invention. The change or adjustment in its relative relation should also be deemed as in the range of implementation of the present invention, without physically changing the technical content.

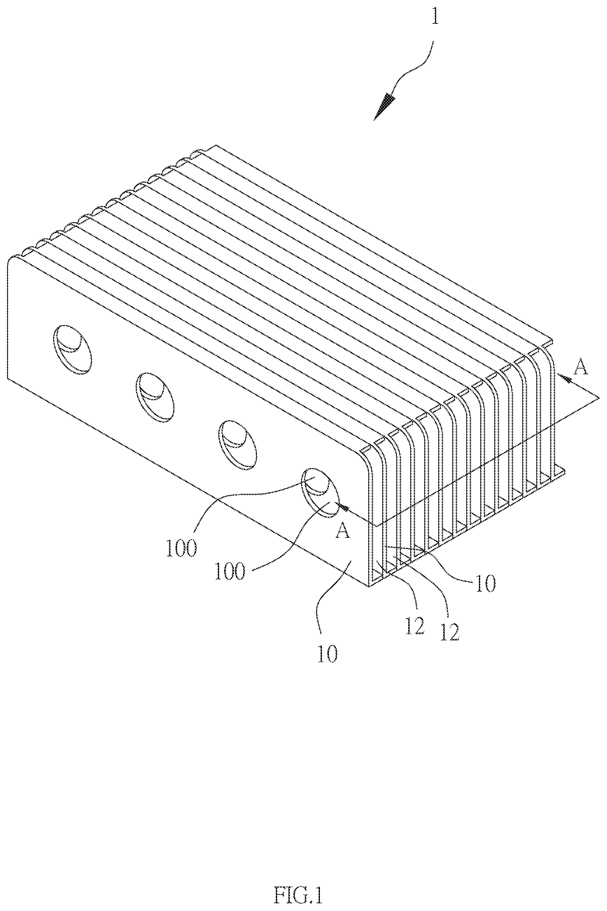

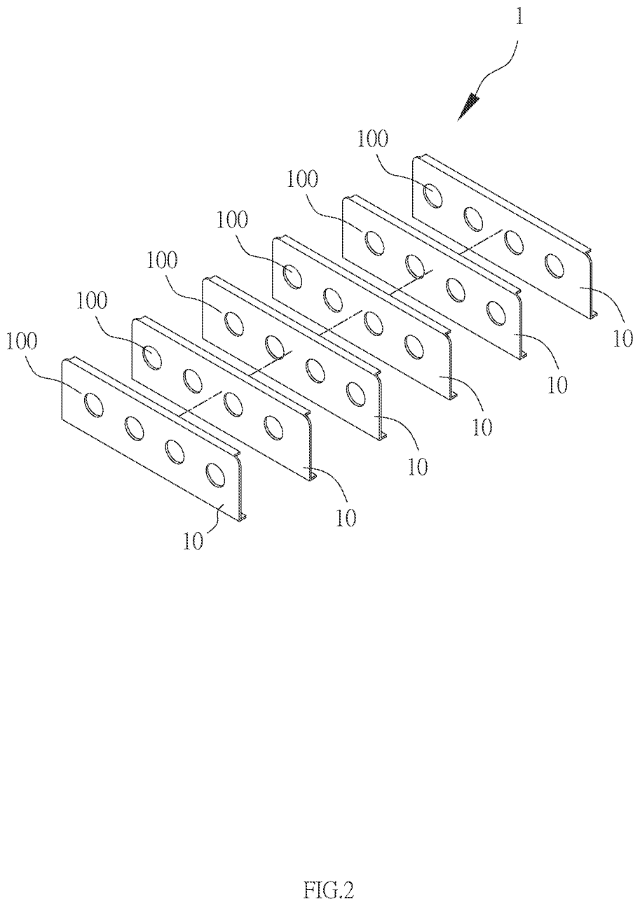

Referring to FIG. 1 and FIG. 2, it shows a three-dimensional schematic view and a three-dimensional exploded view of the preferred embodiment of the present invention. The present invention discloses a heat dissipation structure 1, comprising primarily plural cooling fins 10. A flow space 12 for air flow is defined between every two cooling fins 10, and at least a through-hole 100 which is connected with the flow space 12 is defined on each cooling fin 10.

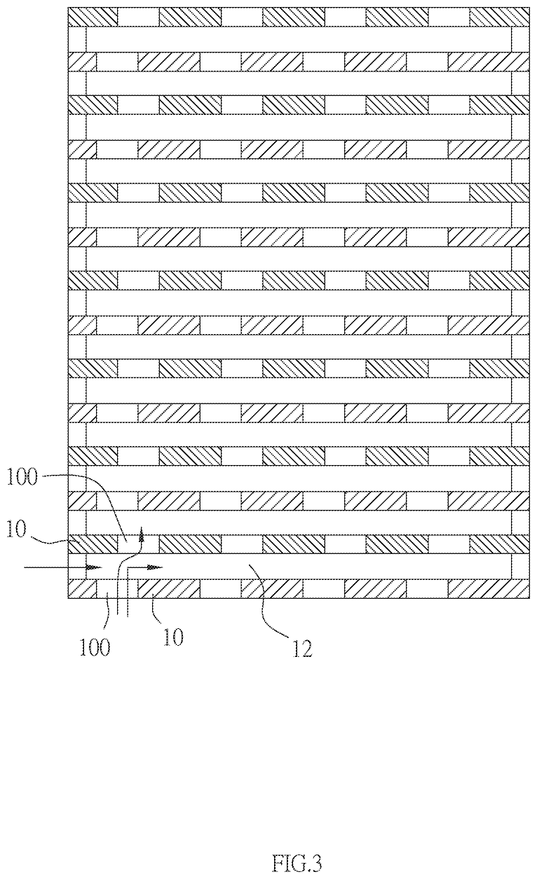

In addition to FIG. 1 and FIG. 2, please refer to FIG. 3, which shows a schematic view of air flow direction along a section line AA in FIG. 1. As shown in the drawing, the air flow direction of the through-hole 100 on the cooling fin 10 is perpendicular to the direction of air flow in the flow space 12. From the direction of arrow, the transversally connected flow space 12 of the cooling fin 10 in the entire heat dissipation structure 1 is provided with an air flow effect, the through-hole 100 formed on the cooling fin 10 is configured longitudinally and is connected with the flow space 12. Therefore, the air flow efficiency can be improved significantly, which improves the heat dissipation effect correspondingly. In addition, as there are many through-holes 100 configured on each cooling fin 10, the weight of entire finished product is reduced indirectly.

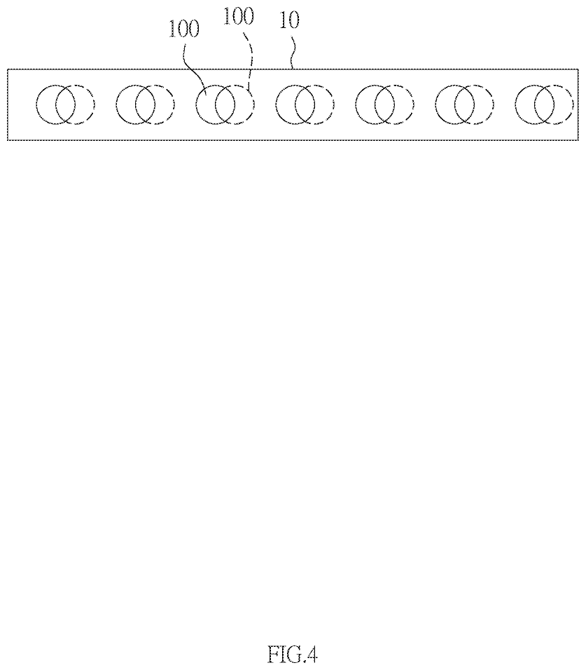

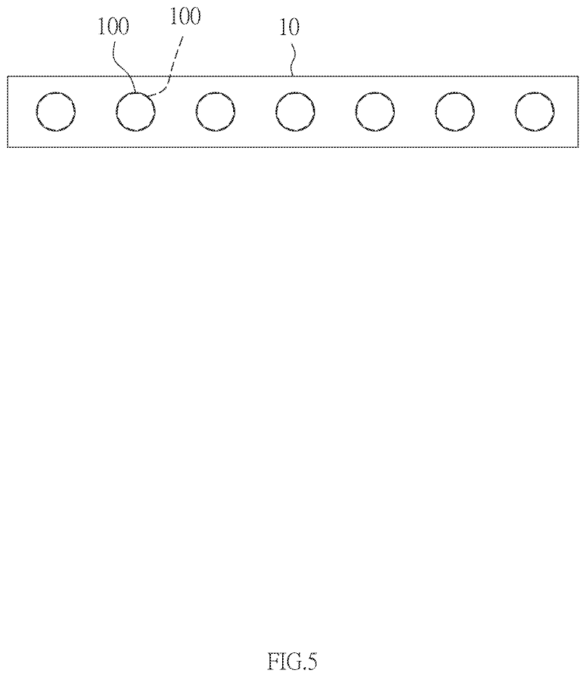

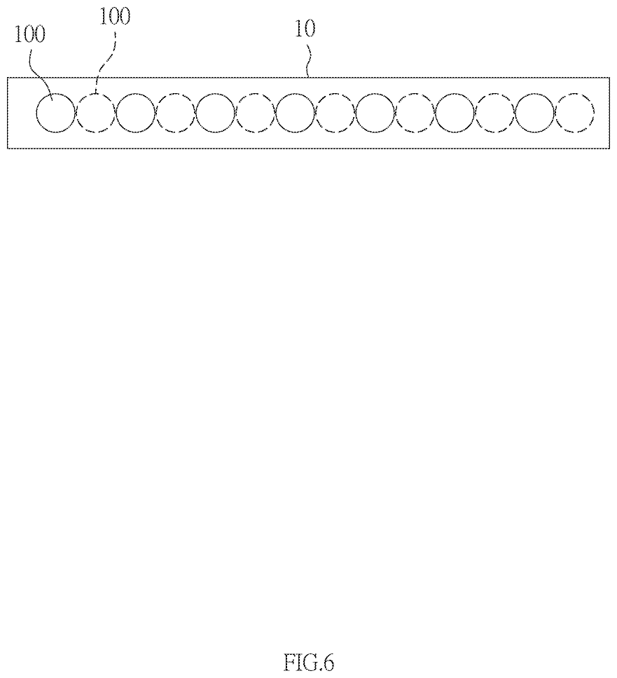

In addition to FIGS. 1 to 3, please refer to FIGS. 4 to 6, showing a state diagram that the through-holes on the cooling fin are partly overlapped with the through-holes on a neighboring cooling fin, a state diagram that the through-holes on the cooling fin are completely overlapped with the through-holes on a neighboring cooling fin, and a state diagram that the through-holes on the cooling fin are not overlapped with the through-holes on a neighboring cooling fin. As shown in FIG. 4, it can be seen along a lateral direction of the heat dissipation structure 1 that the through-holes 100 in each cooling fin 10 are partly overlapped with the through-holes 100 in a neighboring cooling fin 10, meaning that from the overlapped part, the rear structure can be seen through. Therefore, part of air can cross over the through-holes 100 in each cooling fin 10 linearly and directly, thereby improving the heat removal efficiency. On the other hand, in FIG. 5, the through-holes 100 in each cooling fin 10 are completely overlapped with the through-holes 100 in a neighboring cooling fin 10, meaning that from the through-holes 100, the rear structure can be seen through completely without being shielded. Therefore, air can completely cross over the through-holes 100 in each cooling fin 10 linearly and directly, thereby providing a better heat removal efficiency than that in FIG. 4. Finally, in FIG. 6, the through-holes 100 in each cooling fin 10 are not overlapped with the through-holes 100 in a neighboring cooling fin 10, meaning that from the through-holes 100 in the cooling fin 10, the rear structure cannot be seen through. As the flowing air cannot cross over the through-hole 100 in each cooling fin 10 linearly and directly, a roundabout method can be used, and this can still improve the air flow efficiency significantly to improve the heat removal effect correspondingly. As each abovementioned cooling fin 10 is provided with plural through-holes 100, the weight of entire finished product can be reduced.

The through-holes 100 on the cooling fin 10 disclosed by the present invention can be in a circular, elliptical, polygonal or irregular shape. In the present embodiment, the circular through-hole is disclosed as an example.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A heat dissipation structure, comprising plural cooling fins, wherein a flow space for air flow is defined between every two cooling fins, and a through-hole which is connected with the flow space is defined on each cooling fin.

2. The heat dissipation structure according to claim 1, wherein the cooling fin is provided with plural through-holes.

3. The heat dissipation structure according to claim 2, wherein the through-holes on a cooling fin are partly overlapped with the through-holes on a neighboring cooling fin.

4. The heat dissipation structure according to claim 2, wherein the through-holes on a cooling fin are completely overlapped with the through-holes on a neighboring cooling fin.

5. The heat dissipation structure according to claim 2, wherein the through-holes on a cooling fin are not overlapped with the through-holes on a neighboring cooling fin.

6. The heat dissipation structure according to claim 1, wherein the air flow direction of the through-hole on the cooling fin is perpendicular to the direction of air flow in the flow space.

7. The heat dissipation structure according to claim 1, wherein the through-hole on the cooling fin is in a circular, elliptical, polygonal or irregular shape.
